(19) United States
(12) Patent Application Publication
(10) Pub. No.: US 2022/0231141 A1
(43) Pub. Date: Jul. 21, 2022

(54) HIGH DIELECTRIC CONSTANT METAL GATE MOS TRANSISTOR

(71) Applicant: SHANGHAI HUALI INTEGRATED CIRCUIT CORPORATION, Shanghai (CN)

(72) Inventors: Chengchang Wei, Shanghai (CN); Bingxun Su, Shanghai (CN); Debiao He, Shanghai (CN); Fangrui Wu, Shanghai (CN)

(21) Appl. No.: 17/515,546

(22) Filed: Oct. 31, 2021

(30) Foreign Application Priority Data
Jan. 18, 2021 (CN) 202110059785.X

(51) Int. Cl. H01L 29/423; H01L 27/092

(52) U.S. Cl. CPC H01L 29/42364; H01L 29/42372; H01L 27/092

(57) ABSTRACT

A high dielectric constant metal gate MOS transistor comprises a gate dielectric layer, a metal work function layer, a top capping layer, and a metal conductive material layer. The gate dielectric layer comprises a high dielectric constant layer; the top capping layer comprises a material that prevents metal ions of the metal conductive material layer from diffusing downwards into the metal work function layer. The top capping layer has a non-crystalline structure, which reduces or eliminates oxygen diffusion paths, thereby no oxidation of the surface of the metal work function layer occurs. The work function offset from this oxidation is eliminated, thereby preventing a drift of the threshold voltage of the MOS transistor.

### CROSS-REFERENCES TO RELATED APPLICATIONS

This application claims the priority to Chinese patent application No. CN202110059785.X, filed on Jan. 18, 2021, and entitled “HIGH DIELECTRIC CONSTANT METAL GATE MOS TRANSISTOR”, the disclosure of which is incorporated herein by reference in entirety.

### TECHNICAL FIELD

The present application relates a semiconductor integrated circuit, in particular to a high dielectric constant metal gate (HKMG) MOS transistor.

### BACKGROUND

With development of the CMOS technology, the conventional silicon dioxide gate dielectric and polysilicon gate (Poly SiON) transistors have reached their physical limits. For example, the problem of excessively large leakage current caused by the quantum tunneling effect and the problem of depletion of the polysilicon gate have seriously affected the performance of the semiconductor devices. Starting from the 45 nm technology node, the HKMG stacked transistor developed on the basis of the HKMG process effectively solves the above technical problems.

An HKMG is used in the gate structure of a high dielectric constant metal gate MOS transistor. The HKMG includes a high dielectric constant layer (HK) and a metal gate (MG), wherein the metal gate includes a metal work function layer and a metal conductive material layer. The work function layer is used to adjust the threshold voltage of the device, that is, different work functions of the metal work function layer correspond to different flat band voltages of the device, resulting in different threshold voltages of the device. The metal work function layer of an NMOS is an N-type metal work function layer, wherein the work function of the N-type metal work function layer is generally close to the bottom of the conduction band of a semiconductor substrate such as a silicon substrate, so that the threshold voltage of the NMOS can be reduced, thereby facilitating the improvement of the device speed and reduction of the power consumption. The metal work function layer of a PMOS is a P-type metal work function layer, wherein the work function of the P-type metal work function layer is generally close to the top of the valence band of a semiconductor substrate such as a silicon substrate, so that the threshold voltage of the PMOS, i.e., the absolute value of the threshold voltage of the PMOS can be reduced, thereby facilitating the improvement of the device speed and reduction of the power consumption.

For the formation process of the metal gate, a gate-last deposition process is generally adopted, and for the gate dielectric layer including a high dielectric constant layer, an HK-first deposition process or an HK-last deposition process is adopted.

In the gate-last deposition process, a dummy polysilicon gate is required. The dummy polysilicon gate is used to define a formation area of the gate structure, then a sidewall and a source-drain area are formed by means of self-alignment process, after a first interlayer film is formed, the first interlayer film is generally planarized to expose the surface of the dummy polysilicon gate, then the dummy polysilicon gate is removed and a trench is formed in an area from which the dummy polysilicon gate is removed, and subsequently, an HKMG is formed in the trench. In the HK-first deposition process, the gate dielectric layer is formed before the deposition of the dummy polysilicon gate; in this case, after the trench is formed, the gate dielectric layer is already formed at the bottom of the trench, so it is natural to fill the trench with the metal gate. In the HK-last deposition process, the dummy gate dielectric layer is used to replace the gate dielectric layer before the deposition of the dummy polysilicon gate, and the dummy gate dielectric layer is generally a gate oxide layer; in this case, after the trench is formed, the dummy gate dielectric layer at the bottom of the trench needs to be removed, and the gate dielectric layer and metal gate are then formed in the trench.

The N-type metal work function layer of the NMOS is made of TiAl, the P-type metal work function layer of the PMOS is generally made of TiN, and the metal conductive material layer is generally made of Al. In order to prevent Al from diffusing downwards, a top capping layer is generally provided between the metal work function layer and the metal conductive material layer. In a CMOS process, the NMOS and PMOS are integrated on the same semiconductor substrate. In the common integration process, full deposition is generally performed first to form the P-type metal work function layer, then the P-type metal work function layer in an NMOS formation area is removed, and then full deposition is performed to form the N-type metal work function layer; in this case, in a PMOS formation area, the N-type metal work function layer is superposed on the top of the P-type metal work function layer. After the N-type metal work function layer is formed, the top capping layer is formed, and then the metal conductive material layer is formed. Generally, after the top capping layer is formed, the metal conductive material layer is grown after a queue time (Q-time). The existing top capping layer is made of a TiN film. The TiN film can prevent Al from diffusing downwards, and the TiN film has a columnar polycrystalline structure, wherein grains of the columnar polycrystalline structure of the TiN film form a grain boundary that penetrates the entire TiN film, and such the grain boundary is easy to form an oxygen diffusion path, leading to the oxidation of the surface of the bottom metal work function layer. In particular, in the queue time after the formation of the top capping layer and before the formation of the metal conductive material layer, oxygen in the environment is easy to diffuse to the surface of the metal work function layer via the grain boundary of the TiN film, thereby oxidizing the surface of the metal work function layer and forming an oxide layer. After the surface of the metal work function layer is oxidized, the work function of the metal work function layer changes, and the threshold voltage of the device thus changes. Such the change in the threshold voltage is more obvious in the NMOS. Since the N-type metal work function layer of the NMOS is generally made of TiAl, Al in TiAl is easy to be oxidized to form aluminum oxide, the work function of Al is 4.06 eV-4.41 eV, and the work function of Al₂O₃ is 4.7 eV, there is a work function offset of 6.6%-15.7%, resulting in a relatively large offset of the threshold voltage of the NMOS.

In addition, if the queue time after formation of the top capping layer changes, the thickness of the oxidized surface of the metal work function layer also changes. Therefore, the change in the queue time after the formation of the top capping layer also affects the fluctuation of the threshold voltage.

Compared with the gate structure of a planar MOS transistor in which a channel area is controlled from only one face, in the gate structure of a fin transistor (FinFET), a channel area is controlled from more than two faces, such as two side surfaces and top surface of the fin, so as to improve the performance of the device. When the process node is reduced to below 25 nm, the existing planar MOS transistor has the problem of a relatively large electric leakage, so the FinFET is generally adopted. In the planar MOS transistor, the threshold voltage (Vt) is significantly affected by the doping concentration of the channel area, and a threshold voltage offset is primarily determined by an offset of the doping concentration of the channel area. However, compared with planar MOS transistors, the doping concentration of the channel region in the FinFET will be lower, which will increase the influence of the shift of the work function in the gate structure on the threshold voltage shift of the device. However, compared with that in the planar MOS transistor, the doping concentration of the channel area in the FinFET is relatively low, thereby enhancing the impact of the work function offset in the gate structure on the threshold voltage offset of the device.

Further description is made as the following with reference to FIGS. 1 and 2.

FIG. 1 is a cross sectional view of the structure cut along a channel length direction of an existing high dielectric constant metal gate MOS transistor; and

FIG. 2 is a schematic diagram showing oxygen diffusion paths taken by the oxygen molecules from the top capping layer in the existing high dielectric constant metal gate MOS transistor shown in FIG. 1. Herein the NMOS is used as an example:

The HKMG of the NMOS device contains a stack of layers including a high dielectric constant layer 103, a bottom capping layer 104, a bottom etch stop layer 105, a TiAl layer 106 serving as an N-type metal work function layer, a top capping layer 107 composed of a TiN layer, and a metal conductive material layer 108. Referring to FIG. 2, the top capping layer 107 has columnar polycrystalline structures with a grain boundary 201 between two adjacent columns. Each grain boundary 201 forms an easier oxygen diffusion path, resulting in faster oxygen diffusion as indicated by the mark 202. After O₂ molecules diffuse to the surface of the TiAl layer 106, the TiAl layer 106 is oxidized to form a TiAl oxide layer 203. The TiAl oxide layer 203 contains aluminum oxide, thus, the actual N-type metal work function layer contains the stack of the TiAl layer 106 and the TiAl oxide layer 203. Since the work function of the TiAl oxide layer 203 is different from the work function of the TiAl layer 106, an offset of the work function of the N-type metal work function layer occurs, resulting in an offset of the threshold voltage of the NMOS.

In FIG. 1, the HKMG is formed on the surface of a semiconductor substrate 101, and an interface layer is formed between the high dielectric constant layer 103 and the semiconductor substrate 101. Generally, the gate dielectric layer includes the interface layer, the high dielectric constant layer 103, and the bottom capping layer 104. The bottom capping layer 104 is generally a TiN layer, and the bottom capping layer 104 protects the high dielectric constant layer 103 from above. In the HK-first deposition process, the gate dielectric layer formed by stacking the interface layer, the high dielectric constant layer 103, and the bottom capping layer 104 is formed before the deposition of the dummy polysilicon gate. The gate dielectric layer in FIG. 1 is formed by means of the HK-last deposition process, in which case after the dummy polysilicon gate is removed, the gate dielectric layer is disposed on the side surfaces of the trench inside the first interlayer film 102.

Finally the bottom etch stop layer 105, the TiAl layer 106, the top capping layer 107, and the metal conductive material layer 108 form a metal gate.

The first source-drain area 110a and a second source-drain area 110b are respectively formed on two sides of the HKMG.

### BRIEF SUMMARY

The present application provides a high dielectric constant metal gate MOS transistor, with this structure the work function offset of the metal work function layer is prevented, thereby avoiding a drift of the threshold voltage of the device.

According to embodiments of the present application, a HKMG MOS transistor includes a semiconductor substrate; a gate dielectric layer; a metal work function layer; a top capping layer; and a metal conductive material layer; wherein the gate dielectric layer comprises a high dielectric constant layer; wherein the metal work function layer is arranged to be on a top surface of the gate dielectric layer; wherein the top capping layer is arranged in between the metal work function layer and the metal conductive material layer, wherein the top capping layer comprises a material that prevents metal ions of the metal conductive material layer from diffusing downwards into the metal work function layer; and wherein the top capping layer comprises a non-crystalline structure.

In some examples, the HKMK MOS transistor further comprise an NMOS, wherein a metal work function layer of the NMOS is an N-type metal work function layer.

In some examples, the HKMG MOS transistor further comprises a PMOS, wherein the NMOS and the PMOS are integrated on the semiconductor substrate; and wherein a metal work function layer of the PMOS is a P-type metal work function layer.

In some examples, the N-type metal work function layer is superposed on a surface of the P-type metal work function layer in an area of the PMOS; wherein the P-type metal work function layer is at least partially removed in an area of the NMOS, such that a remaining thickness of the P-type metal work function layer in the area of the NMOS is less than a thickness of the P-type metal work function layer in the area of the PMOS.

In some examples, the metal conductive material layer comprises aluminum (Al); wherein the top capping layer comprises a multi-element mixed layer, and has a non-crystalline structure.

In some examples, the top capping layer comprises TiSiN and or ZrTiNi.

In some examples, the N-type metal work function layer comprises one of TiAl, TiAlC, and TiAlN.

In some examples, the P-type metal work function layer comprises TiN.

In some examples, the semiconductor substrate comprises silicon.

In some examples, the HKMG MOS transistor is a fin transistor, wherein a fin is formed on the semiconductor substrate, and wherein the HKMG is configured to be on a top surface or a side surface of the fin.

In some examples, the gate dielectric layer further comprises an interface layer, and wherein the interface layer is arranged between the semiconductor substrate and the high dielectric constant layer.

In some examples, the interface layer comprises silicon oxide.

In some examples, the high dielectric constant layer comprises hafnium dioxide.

In some examples, the gate dielectric layer further comprises a bottom capping layer, and wherein the bottom capping layer protects the gate dielectric layer.

In some examples, the bottom capping layer comprises TiN.

In some examples, a bottom etch stop layer is further provided between the bottom capping layer and the metal work function layer, and wherein the bottom etch stop layer stops etching of the metal work function layer.

In some examples, the bottom etch stop layer comprises TaN.

In the present application, the material of the top capping layer on the top of the metal work function layer of the high dielectric constant metal gate MOS transistor is set to be a non-crystalline structure. Compared with a polycrystalline structure, the non-crystalline structure has no grain boundary that penetrates through the entire thickness of the polycrystalline structure, and therefore, no oxygen diffusion path resulting from the grain boundary is formed. That is, the oxygen diffusion path can be reduced or eliminated, thereby reducing or completely preventing oxygen diffusion to the surface of the metal work function layer that leads to oxidation of the surface of the metal work function layer. Therefore, in the present application, the oxidized structure on the surface of the metal work function layer can be reduced or eliminated, that is, the oxidized structure on the surface of the metal work function layer is reduced or eliminated into a low-oxidized or non-oxidized structure. In this way, an offset of the work function caused by the oxidation of the surface of the metal work function layer can be prevented, thereby preventing a drift of the threshold voltage of the device.

Since the oxygen diffusion primarily occurs in a process queue time after formation of the top capping layer and before formation of the metal conductive material layer, the structure of the top capping layer of the present application can particularly prevent the oxygen diffusion occurring in the queue time after the formation of the top capping layer and before the formation of the metal conductive material layer. Thus, even if the queue time changes, the threshold voltage of the device can still be stabilized. Therefore, in the present application, a tolerance of the queue time after the formation of the top capping layer can be increased, thereby facilitating manufacturing.

The present application is particularly applicable to the NMOS of which the metal work function layer thereof is the N-type metal work function layer. The material of the N-type metal work function layer generally comprises the Al element. The aluminum oxide formed after the Al element is oxidized causes a relatively large offset of the work function of the N-type metal work function layer. Therefore, in the present application, the offset of the work function of the N-type metal work function layer can be prevented well, thereby preventing the drift of the threshold voltage of the NMOS.

Since the work function of a metal work function layer of a FinFET has a relatively large impact on the threshold voltage of the device, the present application is particularly applicable to the FinFET structure, in reducing the fluctuation of the threshold voltage of the FinFET device and improving the stability of the threshold voltage of the FinFET.

### BRIEF DESCRIPTION OF THE DRAWINGS

The present application will be further described in detail below with reference to the drawings and specific implementations:

FIG. 1 is a cross sectional view of the structure cut along a channel length direction of an existing high dielectric constant metal gate MOS transistor.

FIG. 2 is a schematic diagram showing oxygen diffusion paths taken by the oxygen molecules from the top capping layer of the existing high dielectric constant metal gate MOS transistor shown in FIG. 1.

FIG. 3 is a cross sectional view of the structure cut along a channel length direction of a dielectric constant metal gate MOS transistor according to an embodiment of the present application.

FIG. 4 is a cross sectional view of the structure cut along a channel width direction of the dielectric constant metal gate MOS transistor according to an embodiment of the present application.

FIG. 5 is a schematic diagram showing that oxygen diffusion paths shown in FIG. 3 have been eliminated from the top capping layer of the high dielectric constant metal gate MOS transistor, according to an embodiment of the present application.

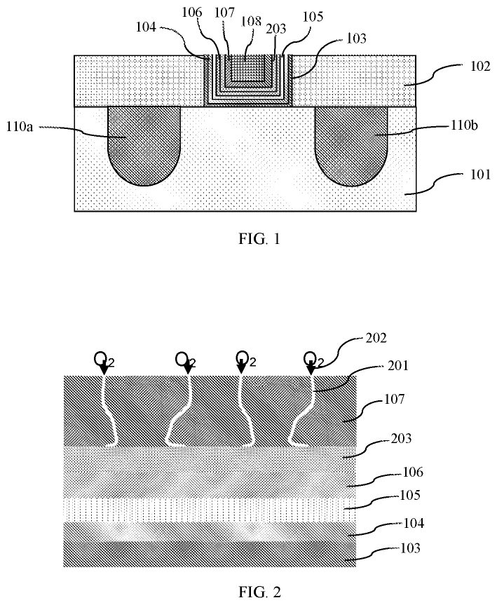

### DETAILED DESCRIPTION OF THE DISCLOSURE

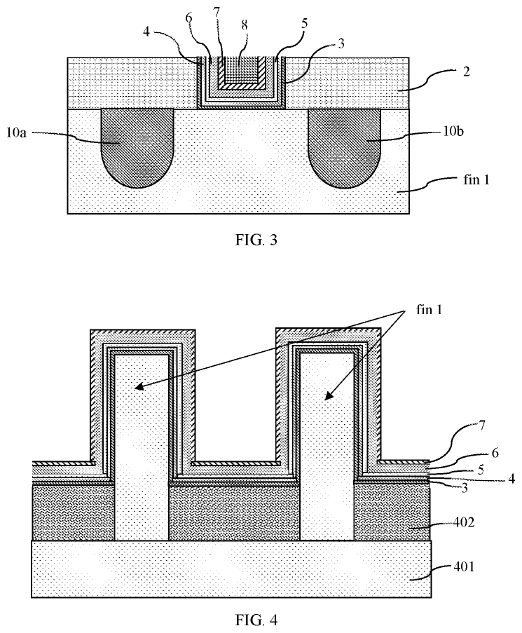

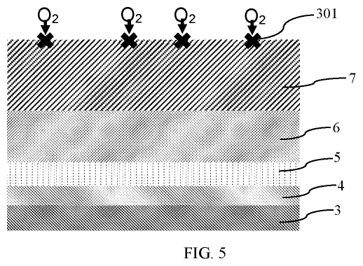

Referring to FIG. 3, FIG. 3 is the cross sectional view of the structure cut along a channel length direction of a dielectric constant metal gate MOS transistor according to an embodiment of the present application, and the dielectric constant metal gate MOS transistor shown in FIG. 3 is an NMOS. FIG. 4 is the cross sectional view of the structure cut along a channel width direction of the dielectric constant metal gate MOS transistor according to an embodiment of the present application. FIG. 5 is a schematic diagram showing that the oxygen diffusion paths shown in FIG. 3 have been eliminated from the top capping layer 7 of the high dielectric constant metal gate MOS transistor, according to an embodiment of the present application. Taking the NMOS as an example, a high dielectric constant metal gate of the high dielectric constant metal gate MOS transistor in an embodiment of the present application is formed on a semiconductor substrate 401.

The high dielectric constant metal gate includes a gate dielectric layer, a metal work function layer, the top capping layer 7, and a metal conductive material layer 8.

The gate dielectric layer includes a high dielectric constant layer 3.

The metal work function layer is arranged on the top of the gate dielectric layer.

The top capping layer 7 is arranged between the metal work function layer and the metal conductive material layer 8, and the top capping layer 7 is made of a material that prevents metallic ions of the metal conductive material layer 8 from diffusing downwards into the metal work function layer.

The top capping layer 7 has a non-crystalline structure, which reduces or eliminates oxygen diffusion paths, thus decreasing oxidation of the surface of the metal work function layer, thereby preventing an oxidized film growing on the surface of the metal work function layer.

The high dielectric constant metal gate MOS transistor includes an NMOS, and a metal work function layer of the NMOS is an N-type metal work function layer 6. Referring to FIG. 5, those grain boundaries 201 between the columnar grains as shown in FIG. 2 have been eliminated from the top capping layer 7, so the top capping layer 7 shows no oxygen diffusion paths at locations marked by 301. In this embodiment of the present application, O₂ are prevented from diffusing through the top capping layer 7 to the N-type metal work function layer 6, such that the surface of the N-type metal work function layer 6 is not oxidized, that is, there is no TiAl oxide layer 203 as shown in FIG. 2. In other embodiments, the top capping layer 7 reduces the oxygen diffusion paths, decreasing oxidation on the surface of the metal work function layer, thereby preventing forming the oxidized structure on the surface of the metal work function layer, as the result, forming a low-oxidized structure.

The high dielectric constant metal gate MOS transistor further includes a PMOS, and the NMOS and the PMOS are integrated on the same semiconductor substrate 401. A metal work function layer of the PMOS is a P-type metal work function layer (not shown in the figures).

In a formation area of the PMOS, the N-type metal work function layer 6 is superposed on the surface of the P-type metal work function layer. In a formation area of the NMOS, the P-type metal work function layer is completely removed. Alternatively, in the formation area of the NMOS, the P-type metal work function layer is partially removed so that the thickness of the P-type metal work function layer remaining in the formation area of the NMOS is less than the thickness of the P-type metal work function layer in the formation area of the PMOS. The thickness of the P-type metal work function layer removed from the formation area of the NMOS can be set according to actual needs.

The material of the metal conductive material layer 8 includes Al.

A multi-element mixed layer is used as the material of the top capping layer 7 to form the non-crystalline structure. In some examples, the material of the top capping layer 7 includes TiSiN and ZrTiNi.

The material of the N-type metal work function layer 6 includes TiAl, TiA1C, and TiAlN.

The material of the P-type metal work function layer includes TiN.

The semiconductor substrate 401 includes silicon.

In this embodiment of the present application, the high dielectric constant metal gate MOS transistor is a fin transistor, a fin 1 is formed on the semiconductor substrate 401, and the high dielectric constant metal gate covers the top surface or side surface of the fin 1.

The fin 1 is formed by etching the semiconductor substrate 401. The cross section in FIG. 3 is viewed along the length direction of the fin 1, i.e., the channel length direction. In FIG. 3, the fin 1 and the semiconductor substrate 401 are integrated as a whole, and the semiconductor substrate 401 is arranged to be at the bottom of the fin 1.

The cross section in FIG. 4 is viewed along the width direction of the fin 1, i.e., the channel width direction. Generally, the fins 1 on the semiconductor substrate 401 are arranged in parallel, and those HKMGs of NMOSs configured in the same row or PMOSs configured in the same row are formed at the same time, so that the HKMGs in the same row cover the top surfaces and side surfaces of the fins 1 and the top surface of a field oxide 402 between the fins 1. FIG. 4 shows two fins 1. Since a direction from a source area to a drain area is the channel length direction, the source area and the drain area are not shown in FIG. 4, and a first source-drain area 10a and a second source -drain area 10b are shown in FIG. 3. In FIG. 3, the first source-drain area 10a and the second source-drain area 10b are arranged symmetrically, one of the first source-drain area 10a and the second source-drain area 10b is the source area, and the other of the first source-drain area 10a and the second source-drain area 10b is the drain area.

The gate dielectric layer further includes an interface layer, and the interface layer is arranged between the semiconductor substrate 401 and the high dielectric constant layer 3. The material of the interface layer includes silicon oxide.

The material of the high dielectric constant layer 3 includes hafnium dioxide.

The gate dielectric layer further includes a bottom capping layer 4, and the bottom capping layer 4 is used to protect the gate dielectric layer. The material of the bottom capping layer 4 includes TiN.

A bottom etch stop layer 5 is further provided between the bottom capping layer 4 and the metal work function layer, and the bottom etch stop layer 5 serves as a stop layer for etching of the metal work function layer. The material of the bottom etch stop layer 5 includes TaN.

In the HKMG of the NMOS shown in to FIG. 3 according to the embodiment of the present application, the gate dielectric layer is formed by stacking up the interface layer, the high dielectric constant layer 3, and the bottom capping layer 4. The metal gate is formed by stacking up the bottom etch stop layer 5, the N-type metal work function layer 6, the top capping layer 7, and the metal conductive material layer 8.

In the structure shown in FIG. 3, the gate dielectric layer is formed by means of a HK-last deposition process, and the metal gate is formed by means of a HK-first deposition process. A dummy gate dielectric layer and a dummy polysilicon gate are required in the formation process. A formation area of a gate structure is defined by means of the dummy polysilicon gate, sidewalls of the dummy polysilicon gate gate are formed on the side surface of the dummy polysilicon gate by means of self-alignment deposition, and the first source-drain area 10a and the second source-drain area 10b are formed by means of self-alignment implantation. A formation process of the first source-drain area 10a and the second source-drain area 10b includes ion implantation and annealing activation.

Next step is forming a contact etch stop layer (CESL) and then a first interlayer film 2, followed by planarization and etching back on the first interlayer film 2 is to expose the surface of the dummy polysilicon gate.

Subsequently, a gate replacement process is performed, including: removing the dummy polysilicon gate to form a trench; removing the dummy gate dielectric layer at the bottom of the trench; and then forming, in the trench, the gate dielectric layer and the metal gate, according to the embodiment of the present application.

The gate dielectric layer can also be formed by means of a HK-first deposition process, in this case, in the gate dielectric layer formation process, no dummy gate dielectric layer is required, instead the gate dielectric layer is directly formed, followed by forming the dummy polysilicon gate. After disposing the first interlayer film 2, completing the planarization and etching back, the dummy polysilicon gate is removed to form a trench, and then the metal gate is directly formed in the trench.

In the present application, the material of the top capping layer on the surface of the metal work function layer of the high dielectric constant metal gate MOS transistor has a non-crystalline structure. Compared with the polycrystalline structure, the non-crystalline structure contains no grain boundaries which allow diffusing oxygen molecules to penetrate through the entire layer of the polycrystalline structure, and therefore, the non-crystalline structure eliminates oxygen diffusion paths from the grain boundaries, thereby reducing or completely removing oxygen diffusion into the surface of the metal work function layer that leads to oxidation of the surface of the metal work function layer. Therefore, in the present application, there is no oxidized film on the surface of the metal work function layer. In other words, the defect from the oxidized film left on the surface of the metal work function layer by the existing technology is at least reduced. As the result, the offset of the work function caused by the existing oxidation on the surface of the metal work function layer is prevented, thereby preventing a drift of the threshold voltage of the transistor.

Since the oxygen diffusion primarily occurs in a process queue time after forming the top capping layer 7 and before disposing the metal conductive material layer 8, the disclosed process of making the top capping layer 7 in the present application is targeted to prevent the oxygen diffusion from occurring in the process queue time between forming the top capping layer 7 and forming of the metal conductive material layer 8. Thus, even if the queue time varies in the process, the threshold voltage of the device will still be stable. Therefore, the present application increases the tolerance of the queue time after forming the top capping layer 7, which improves manufacturing.

The present application is particularly applicable to the NMOS of which the metal work function layer thereof is the N-type metal work function layer 6. The material of the N-type metal work function layer 6 generally includes the Al element. The aluminum oxide formed after the Al element is oxidized causes a relatively large offset of the work function of the N-type metal work function layer 6. Therefore, in the present application, the offset of the work function of the N-type metal work function layer 6 can be prevented well, thereby preventing the drift of the threshold voltage of the NMOS.

Since the work function of a metal work function layer of a FinFET has a relatively large impact on the threshold voltage of the transistor, the disclosed process benefits the FinFET manufacturing, in particular, it improves the stability of the threshold voltage of the FinFET by reducing its fluctuation.

The present application is described in detail above via specific embodiments, but these embodiments are not intended to limit the present application. Without departing from the principle of the present application, those skilled in the art can still make many variations and improvements, which should also be considered to fall into the protection scope of the present application.

1. A high dielectric constant metal gate (HKMG) MOS transistor, comprising:
a semiconductor substrate;
a gate dielectric layer;
a metal work function layer;
a top capping layer; and
a metal conductive material layer;
wherein the gate dielectric layer comprises a high dielectric constant layer;
wherein the metal work function layer is arranged to be on a top surface of the gate dielectric layer;
wherein the top capping layer is arranged in between the metal work function layer and the metal conductive material layer, wherein the top capping layer comprises a material that prevents metal ions of the metal conductive material layer from diffusing downwards into the metal work function layer; and
wherein the top capping layer comprises a non-crystalline structure.

2. The HKMG MOS transistor according to claim 1, further comprising an NMOS,
wherein a metal work function layer of the NMOS is an N-type metal work function layer.

3. The HKMG MOS transistor according to claim 2, further comprising a PMOS,
wherein the NMOS and the PMOS are integrated on the semiconductor substrate; and
wherein a metal work function layer of the PMOS is a P-type metal work function layer.

4. The HKMG MOS transistor according to claim 3, wherein the N-type metal work function layer is superposed on a surface of the P-type metal work function layer in an area of the PMOS; wherein the P-type metal work function layer is at least partially removed in an area of the NMOS, such that a remaining thickness of the P-type metal work function layer in the area of the NMOS is less than a thickness of the P-type metal work function layer in the area of the PMOS.

5. The HKMG MOS transistor according to claim 1, wherein the metal conductive material layer comprises aluminum (Al); wherein the top capping layer comprises a multi-element mixed layer, has a non-crystalline structure.

6. The HKMG MOS transistor according to claim 5, wherein the top capping layer comprises TiSiN or ZrTiNi.

7. The HKMG MOS transistor according to claim 2, wherein the N-type metal work function layer comprises one of TiAl, TiA1C, and TiAlN.

8. The HKMG MOS transistor according to claim 3, wherein the P-type metal work function layer comprises TiN.

9. The HKMG MOS transistor according to claim 1, wherein the semiconductor substrate comprises silicon.

10. The HKMG MOS transistor according to claim 1, wherein the HKMG MOS transistor is a fin transistor, wherein a fin is formed on the semiconductor substrate, and wherein the HKMG is configured to be on a top surface or a side surface of the fin.

11. The HKMG MOS transistor according to claim 1, wherein the gate dielectric layer further comprises an interface layer, wherein the interface layer is arranged between the semiconductor substrate and the high dielectric constant layer.

12. The HKMG MOS transistor according to claim 11, wherein the interface layer comprises silicon oxide.

13. The HKMG MOS transistor according to claim 1, wherein the high dielectric constant layer comprises hafnium dioxide.

14. The HKMG MOS transistor according to claim 1, wherein the gate dielectric layer further comprises a bottom capping layer, wherein the bottom capping layer protects the gate dielectric layer.

15. The HKMG MOS transistor according to claim 14, wherein the bottom capping layer comprises TiN.

16. The HKMG MOS transistor according to claim 14, further comprising a bottom etch stop layer provided between the bottom capping layer and the metal work function layer, wherein the bottom etch stop layer stops etching of the metal work function layer.

17. The HKMG MOS transistor according to claim 16, wherein the bottom etch stop layer comprises TaN.
